(19) United States
(12) Patent Application Publication
(10) Pub. No.: US 2026/0100340 A1
(43) Pub. Date: Apr. 9, 2026

(54) PLASMA PROCESSING APPARATUS AND POTENTIAL CONTROL METHOD

(71) Applicant: Tokyo Electron Limited, Tokyo (JP)

(72) Inventors: Yuki KAWADA, Miyagi (JP); Naoki MATSUMOTO, Miyagi (JP); Kazuhito YAMADA, Miyagi (JP)

(73) Assignee: Tokyo Electron Limited, Tokyo (JP)

(21) Appl. No.: 19/415,795

(22) Filed: Dec. 11, 2025

Related U.S. Application Data
(63) Continuation of application No. PCT/JP2024/021603, filed on Jun. 14, 2024.

(30) Foreign Application Priority Data
Jun. 27, 2023 (JP) 2023-105013

(51) Int. Cl. H01J 37/32

(52) U.S. Cl. CPC H01J 37/32568; H01J 37/32642; H01J 37/32715; H01J 2237/2007; H01J 2237/334

(57) ABSTRACT

A plasma processing apparatus includes a chamber, a stage, a plurality of electrodes, a power supply, a switch, and controller circuitry. The chamber to generate plasma therein. The stage is disposed in the chamber, formed of a dielectric material, receives a substrate thereon and receives a ring assembly thereon around the substrate. The plurality of electrodes are provided in a portion facing the ring assembly inside the stage. The power supply supplies bias power for attracting charged particles in the plasma. The switch individually supplies the bias power supplied from the power supply to the plurality of electrodes. The controller circuitry controls the switch.

### CROSS-REFERENCE TO RELATED APPLICATIONS

This application is a continuation of International Application No. PCT/JP2024/021603, filed on Jun. 14, 2024 which claims the benefit of priority of the prior Japanese Patent Application No. 2023-105013, filed on Jun. 27, 2023, the entire contents of each are incorporated herein by reference.

### FIELD

The present disclosure relates to a plasma processing apparatus and a potential control method.

### BACKGROUND

Japanese Laid-open Patent Publication No. 2012-064671 discloses “a plasma processing apparatus that generates plasma on a substrate and performs predetermined processing, the plasma processing apparatus comprising: a susceptor to which high frequency power is applied, the susceptor having a substrate placement part on which a substrate is placed; a focus ring disposed to surround a periphery of the substrate placed on the substrate placement part, and integrally configured by an outer ring having an upper surface higher than the substrate and an inner ring extending inside the outer ring and below a peripheral edge of the substrate and having an upper surface lower than the substrate; a dielectric ring interposed between the focus ring and the susceptor; a dielectric constant changing mechanism that changes a dielectric constant of the dielectric ring; and a controller that controls an upper surface potential of the focus ring by driving the dielectric constant changing mechanism and adjusting the dielectric constant of the dielectric ring”.

### SUMMARY

In one or more embodiments of a present disclosure, a plasma processing apparatus includes: a chamber to generate plasma therein; a stage disposed in the chamber, formed of a dielectric material, receives a substrate thereon and receives a ring assembly thereon around the substrate; a plurality of electrodes provided in a portion facing the ring assembly inside the stage; a power supply supplying bias power for attracting charged particles in the plasma; a switch individually supplying the bias power supplied from the power supply to the plurality of electrodes; and controller circuitry configured to control the switch.

### BRIEF DESCRIPTION OF DRAWINGS

FIG. 1 is a diagram for explaining a configuration example of a capacitively-coupled plasma processing apparatus;

FIG. 2A is a cross-sectional view illustrating an example of a configuration of a main body part of a substrate support part;

FIG. 2B is an enlarged view of a portion of an electrostatic chuck in which a plurality of electrodes are arranged;

FIG. 3A is a cross-sectional view illustrating another example of a configuration of a main body part of a substrate support part;

FIG. 3B is an enlarged view of a portion of an electrostatic chuck in which a plurality of electrodes are arranged;

FIG. 4 is a circuit diagram schematically illustrating an example of a configuration of a plasma processing apparatus 1;

FIG. 5 is a diagram for explaining a model used for simulation;

FIG. 6 is a diagram for explaining a simulation result;

FIG. 7 is a diagram for explaining a change in processing characteristic of plasma processing;

FIG. 8 is a flowchart illustrating an example of a processing flow of a potential control method;

FIG. 9A is a diagram illustrating another example in which electrodes are arranged;

FIG. 9B is a diagram illustrating an example of a combination of switches turned on and off;

FIG. 10A is a diagram illustrating an example in which an annular region of an electrostatic chuck is divided into a plurality of zones; and

FIG. 10B is a cross-sectional view illustrating an example of a configuration of a main body part in a case where a plurality of electrodes are provided for each zone.

### DETAILED DESCRIPTION

Hereinafter, one or more embodiments of a plasma processing apparatus and a potential control method will be described in detail with reference to the drawings. Note that the plasma processing apparatus and the potential control method disclosed below are not limited by the following one or more embodiments.

Conventionally, plasma processing apparatuses that perform plasma processing such as plasma etching on substrates such as semiconductor wafers (hereinafter also referred to as “wafers”) have been known. In the plasma processing apparatus, a ring assembly such as a focus ring is disposed around a substrate for the purpose of uniformizing plasma. In the plasma processing apparatus, if the height of the boundary surface between the bulk plasma and the sheath (hereinafter referred to as “sheath surface”) changes due to wear on the upper surface of the ring assembly caused by the plasma etching, a change in potential of the ring assembly, or the like, this may affect the processing results for the substrate. For example, if the height of the sheath surface is different between the substrate and the top of the ring assembly, the direction of the electric field is not perpendicular to the substrate in the peripheral portion of the substrate, causing the trajectories of charged particles such as ions in the plasma to be inclined, resulting in a phenomenon such as tilting in which holes are formed obliquely.

The present disclosure provides a technology capable of controlling a potential of a ring assembly without providing an upward-and-downward movement mechanism.

Therefore, a method has been proposed in which a dielectric ring is disposed on the lower surface side of the ring assembly and the dielectric ring is moved upward and downward to adjust the dielectric constant of the ring assembly and control the potential of the ring assembly to a desired value.

However, in the conventional method, it is necessary to provide an upward-and-downward movement mechanism that moves the dielectric ring upward and downward, and particles may be generated from the upward-and-downward movement mechanism. Therefore, a technology capable of controlling the potential of the ring assembly without providing an upward-and-downward movement mechanism is expected.

### Device Configuration

An example of a plasma processing apparatus according to the present disclosure will be described. In the one or more embodiments to be described below, the plasma processing apparatus according to the present disclosure will be described as an example of a plasma processing system having a system configuration.

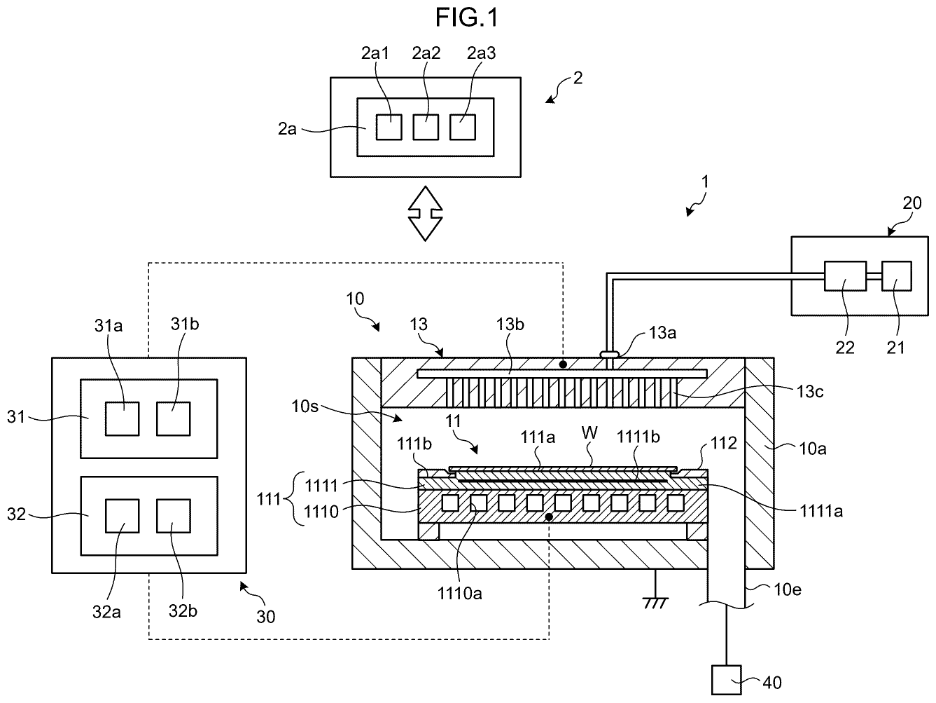

Hereinafter, a configuration example of the plasma processing system will be described. FIG. 1 is a diagram for explaining a configuration example of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply unit 20, a power supply 30, and an exhaust system 40. Further, the plasma processing apparatus 1 includes a substrate support part 11 and a gas introduction part. The gas introduction part is configured to introduce at least one processing gas into the plasma processing chamber 10. The gas introduction part includes a shower head 13. The substrate support part 11 is disposed in the plasma processing chamber 10. The shower head 13 is disposed above the substrate support part 11. In one or more embodiments, the shower head 13 constitutes at least a portion of a ceiling of the plasma processing chamber 10. The plasma processing chamber 10 has a plasma processing space 10s defined by the shower head 13, a side wall 10a of the plasma processing chamber 10, and the substrate support part 11. The plasma processing chamber 10 has at least one gas supply port for supplying at least one processing gas to the plasma processing space 10s and at least one gas discharge port for discharging the gas from the plasma processing space. The plasma processing chamber 10 is grounded. The shower head 13 and the substrate support part 11 are electrically insulated from a housing of the plasma processing chamber 10.

The substrate support part 11 includes a main body part 111 and a ring assembly 112. The main body part 111 has a central region 111a for supporting a substrate W and an annular region 111b for supporting the ring assembly 112. A wafer is an example of the substrate W. The annular region 111b of the main body part 111 surrounds the central region 111a of the main body part 111 in plan view. The substrate W is disposed on the central region 111a of the main body part 111, and the ring assembly 112 is disposed on the annular region 111b of the main body part 111 so as to surround the substrate W disposed on the central region 111a of the main body part 111. Therefore, the central region 111a is also referred to as a substrate support surface for supporting the substrate W, and the annular region 111b is also referred to as a ring support surface for supporting the ring assembly 112.

In one or more embodiments, the main body part 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 is formed of a dielectric material. For example, the electrostatic chuck 1111 is formed of ceramic. The electrostatic chuck 1111 includes a ceramic member 1111a and an electrostatic electrode 1111b disposed in the ceramic member 1111a. The electrostatic chuck 1111 is configured such that the substrate W can be placed thereon, and the ring assembly 112 can also be placed thereon around the substrate W. For example, the ceramic member 1111a has a central region 111a. In one or more embodiments, the ceramic member 1111a also has an annular region 111b. Note that another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32 to be described later may be disposed in the ceramic member 1111a. In this case, at least one RF/DC electrode functions as a lower electrode. When a bias RF signal and/or a DC signal to be described later is provided to at least one RF/DC electrode, the RF/DC electrode is also referred to as a bias electrode. Note that the conductive member of the base 1110 and at least one RF/DC electrode may function as a plurality of lower electrodes. In addition, the electrostatic electrode 1111b may function as a lower electrode. Therefore, the substrate support part 11 includes at least one lower electrode. In the one or more embodiments, the electrostatic chuck 1111 corresponds to a stage according to the present disclosure.

The ring assembly 112 includes one or more annular members. In one or more embodiments, the one or more annular members include one or more edge rings and at least one cover ring. The edge ring is formed of a conductive material or an insulating material, and the cover ring is formed of an insulating material.

The substrate support part 11 may also include a temperature adjustment module configured to adjust at least one of the electrostatic chuck 1111, the ring assembly 112, and the substrate to a target temperature. The temperature adjustment module may include a heater, a heat transfer medium, a flow path 1110a, or a combination thereof. A heat transfer fluid such as brine or gas flows through the flow path 1110a. In one or more embodiments, the flow path 1110a is formed in the base 1110, and one or more heaters are disposed in the ceramic member 1111a of the electrostatic chuck 1111. Further, the substrate support part 11 may include a heat transfer gas supply unit configured to supply heat transfer gas to a gap between the back surface of the substrate W and the central region 111a.

The shower head 13 is configured to introduce at least one processing gas from the gas supply unit 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introduction part may include one or more side gas injectors (SGI) attached to one or more openings formed in the side wall 10a.

The gas supply unit 20 may include at least one gas source 21 and at least one flow controller 22. In one or more embodiments, the gas supply unit 20 is configured to supply at least one processing gas from the corresponding gas source 21 to the shower head 13 via the corresponding flow controller 22. Each flow controller 22 may include, for example, a mass flow controller or a pressure control type flow controller. Additionally, the gas supply unit 20 may include one or more flow modulation devices that modulate or pulse the flow of the at least one processing gas.

The power supply 30 includes an RF power supply 31 coupled to the plasma processing chamber 10 via at least one impedance matching circuit. The RF power supply 31 is configured to provide at least one RF signal (RF power) to the at least one lower electrode and/or the at least one upper electrode. As a result, plasma is formed from the at least one processing gas supplied to the plasma processing space 10s. Accordingly, the RF power supply 31 may function as at least a portion of a plasma generation unit configured to generate plasma from one or more processing gases in the plasma processing chamber 10. In addition, by supplying a bias RF signal to at least one lower electrode, a bias potential can be generated in the substrate W, thereby attracting ion components in the formed plasma into the substrate W.

In one or more embodiments, the RF power supply 31 includes a first RF generation unit 31a and a second RF generation unit 31b. The first RF generation unit 31a is coupled to the at least one lower electrode and/or the at least one upper electrode via the at least one impedance matching circuit, and is configured to generate a source RF signal (source RF power) for generation of plasma. In one or more embodiments, the source RF signal has a frequency in the range of 10 MHz to 150 MHz. In one or more embodiments, the first RF generation unit 31a may be configured to generate a plurality of source RF signals having different frequencies. The generated one or more source RF signals are provided to the at least one lower electrode and/or the at least one upper electrode.

The second RF generation unit 31b is coupled to the at least one lower electrode via the at least one impedance matching circuit, and is configured to generate a bias RF signal (bias RF power). The frequency of the bias RF signal may be the same as or different from the frequency of the source RF signal. In one or more embodiments, the bias RF signal has a lower frequency than the source RF signal. In one or more embodiments, the bias RF signal has a frequency in the range of 100 kHz to 60 MHz. For example, the frequency of the bias RF signal is 400 kHz. In one or more embodiments, the second RF generation unit 31b may be configured to generate a plurality of bias RF signals having different frequencies. The generated one or more bias RF signals are provided to the at least one lower electrode. In one or more embodiments, at least one of the source RF signal and the bias RF signal may also be pulsed. In the one or more embodiments, the power supply 30 or the second RF generation unit 31b corresponds to a power supply according to the present disclosure.

The power supply 30 may also include a DC power supply 32 coupled to the plasma processing chamber 10. The DC power supply 32 includes a first DC generation unit 32a and a second DC generation unit 32b. In one or more embodiments, the first DC generation unit 32a is connected to the at least one lower electrode, and is configured to generate a first DC signal. The generated first bias DC signal is applied to the at least one lower electrode. In one or more embodiments, the second DC generation unit 32b is connected to the at least one upper electrode, and is configured to generate a second DC signal. The generated second DC signal is applied to the at least one upper electrode.

In one or more embodiments, at least one of the first and second DC signals may be pulsed. In this case, a sequence of voltage pulses is applied to the at least one lower electrode and/or the at least one upper electrode. The voltage pulse may have a pulse waveform in a rectangular shape, a trapezoidal shape, a triangular shape, or a combination thereof. In one or more embodiments, a waveform generation unit for generating a sequence of voltage pulses from the DC signal is connected between the first DC generation unit 32a and the at least one lower electrode. Therefore, the first DC generation unit 32a and the waveform generation unit constitute a voltage pulse generation unit. In a case where the second DC generation unit 32b and the waveform generation unit constitute a voltage pulse generation unit, the voltage pulse generation unit is connected to at least one upper electrode. The voltage pulse may have a positive polarity or a negative polarity. The sequence of voltage pulses may also include one or more positive polarity voltage pulses and one or more negative polarity voltage pulses within one cycle. Note that the first and second DC generation units 32a and 32b may be provided in addition to the RF power supply 31, and the first DC generation unit 32a may be provided instead of the second RF generation unit 31b.

The exhaust system 40 can be connected to a gas discharge port 10e provided, for example, at a bottom portion of the plasma processing chamber 10. The exhaust system 40 may include a pressure regulation valve and a vacuum pump. The pressure in the plasma processing space 10s is regulated by the pressure regulation valve. The vacuum pump may include a turbomolecular pump, a dry pump, or a combination thereof.

The controller 2 processes computer-executable instructions that cause the plasma processing apparatus 1 to execute various steps described in the present disclosure. The controller 2 can be configured to control each element of the plasma processing apparatus 1 so as to execute various steps described herein. In one or more embodiments, a part or all of the controller 2 may be included in the plasma processing apparatus 1. The controller 2 may include a processing unit 2a1, a storage 2a2, and a communication interface 2a3. The controller 2 is realized by, for example, a computer 2a. The processing unit 2a1 can be configured to perform various control operations by reading a program from the storage 2a2 and executing the read program. This program may be stored in the storage 2a2 in advance, or may be acquired via a medium when necessary. The acquired program is stored in the storage 2a2, and is read from the storage 2a2 and executed by the processing unit 2a1. The medium may be any of various storage media readable by the computer 2a, or may be a communication line connected to the communication interface 2a3. The processing unit 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

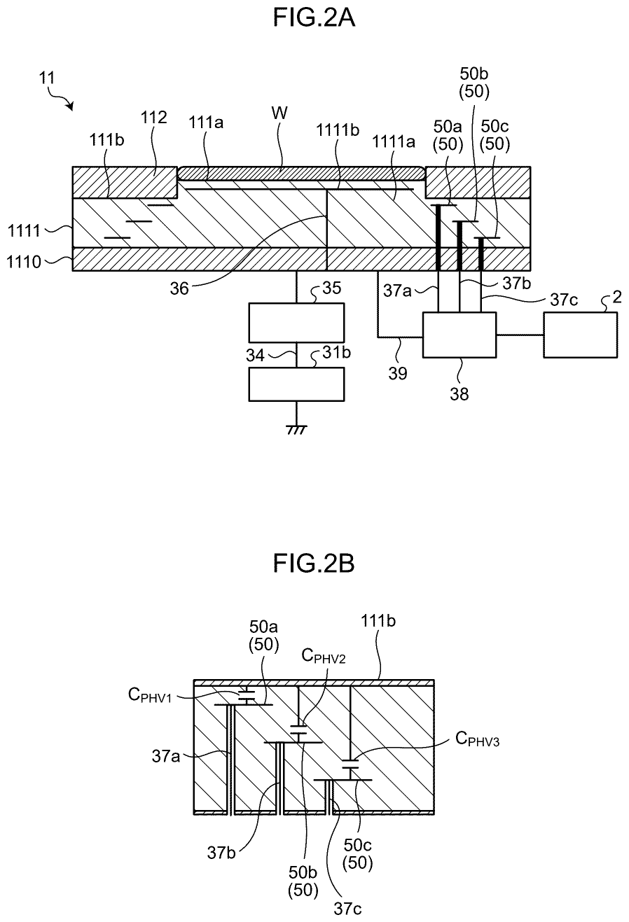

Next, an example of a configuration of the substrate support part 11 will be described. Hereinafter, the components related to the path through which the bias RF signal flows will be mainly described below. FIG. 2A is a cross-sectional view illustrating an example of a configuration of the main body part 111 of the substrate support part 11. FIG. 2A schematically illustrates a cross section of the main body part 111. In the main body part 111, the electrostatic chuck 1111 is provided on the base 1110.

The base 1110 is formed of aluminum, and functions as a lower electrode. The second RF generation unit 31b is connected to the base 1110 via a wire 34. An impedance matching circuit 35 is provided on the wire 34. The impedance matching circuit 35 matches impedance on the second RF generation unit 31b side and impedance on the load side such as the base 1110 and the plasma processing chamber 10.

The substrate W is placed in the central region 111a of the electrostatic chuck 1111. In addition, the ring assembly 112 is placed on the annular region 111b of the electrostatic chuck 1111. In the electrostatic chuck 1111, the electrostatic electrode 1111b is provided in a portion facing the substrate W inside the ceramic member 1111a. In the electrostatic chuck 1111, a plurality of electrodes 50 are provided in a portion facing the ring assembly 112 inside the ceramic member 1111a. Each of the plurality of electrodes 50 is formed in an annular shape to correspond to the annular region 111b. The plurality of electrodes 50 are different in at least one of the depth from the annular region 111b and the area of the surface facing the ring assembly 112 so that the capacitances between the plurality of electrodes 50 and the ring assembly 112 are different. That is, the plurality of electrodes 50 are different in at least one of the distance from the ring assembly 112 and the area of the surface facing the ring assembly 112. The plurality of electrodes 50 are arranged so as not to overlap each other. FIG. 2B is an enlarged view of a portion of the electrostatic chuck 1111 in which the plurality of electrodes 50 are arranged. In FIGS. 2A and 2B, three electrodes 50a to 50c are provided in a portion facing the ring assembly 112 inside the ceramic member 1111a. The electrodes 50a to 50c are provided at different depths from the annular region 111b. The capacitances between the electrodes 50a to 50c and the ring assembly 112 are illustrated as capacitances C_{L1} to C_{L3}. The electrodes 50a to 50c may be formed to have the same area or may be formed to have different areas, as long as the capacitances C_{L1} to C_{L3} between the electrodes 50a to 50c and the ring assembly 112 are different. In FIGS. 2A and 2B, the electrodes 50a to 50c are formed to have the same area, and are arranged in the order from the annular region 111b: the electrode 50a, the electrode 50b, and the electrode 50c. The distance of the electrode 50a from the ring assembly 112 is greatest, the distance of the electrode 50c from the ring assembly 112 is smallest, and the distance of the electrode 50b from the ring assembly 112 is between the distances of the electrodes 50a and 50c from the ring assembly 112. Therefore, the capacitances C_{L1} to C_{L3} satisfy C_{L1}>C_{L2}>C_{L3}. Note that the order in which the distance from the ring assembly 112 becomes larger is not limited to the order: the electrode 50a, the electrode 50b, and the electrode 50c. For example, the electrodes 50a to 50c may be formed such that the distance from the ring assembly 112 becomes larger in the order: the electrode 50a, the electrode 50b, and the electrode 50c, or may be formed such that the distance from the ring assembly 112 becomes larger in the order: the electrode 50a, the electrode 50c, and the electrode 50b. That is, the order of magnitude between the distances between the electrodes 50a, 50c, and 50b and the ring assembly 112 may be arbitrarily changed.

The electrostatic electrode 1111b is connected to the base 1110 via a wire 36. The three electrodes 50a to 50c are connected to a switch mechanism 38 via wires 37a to 37c, respectively. The switch mechanism 38 is connected to the base 1110 via a wire 39.

The second RF generation unit 31b supplies a bias RF signal to the base 1110 via the wire 34. The impedance matching circuit 35 matches impedance on the second RF generation unit 31b side and impedance on the load side. By performing impedance matching using the impedance matching circuit 35, it is possible to suppress power loss such as reflection of the bias RF signal and heat generation in the impedance matching circuit 35.

The bias RF signal supplied to the base 1110 is supplied to the electrostatic electrode 1111b via the wire 36, and is supplied to the switch mechanism 38 via the wire 39. The switch mechanism 38 is configured to individually supply the bias RF signal supplied from the second RF generation unit 31b to the electrodes 50a to 50c via the wires 37a to 37c. For example, the switch mechanism 38 incorporates switches individually connected to the wires 37a to 37c, and is configured to individually supply the bias RF signal to the electrodes 50a to 50c via the wires 37a to 37c by switching the respective switches on/off. In a case where an RF signal such as a bias RF signal is turned on/off, for example, a bidirectional switch can be used as the switch. In the one or more embodiments, the switch mechanism 38 corresponds to a switch unit (i.e., switch) according to the present disclosure.

The controller 2 is connected to the switch mechanism 38. The controller 2 controls the switch mechanism 38. For example, the controller 2 outputs a signal for controlling each switch of the switch mechanism 38 to be turned on/off.

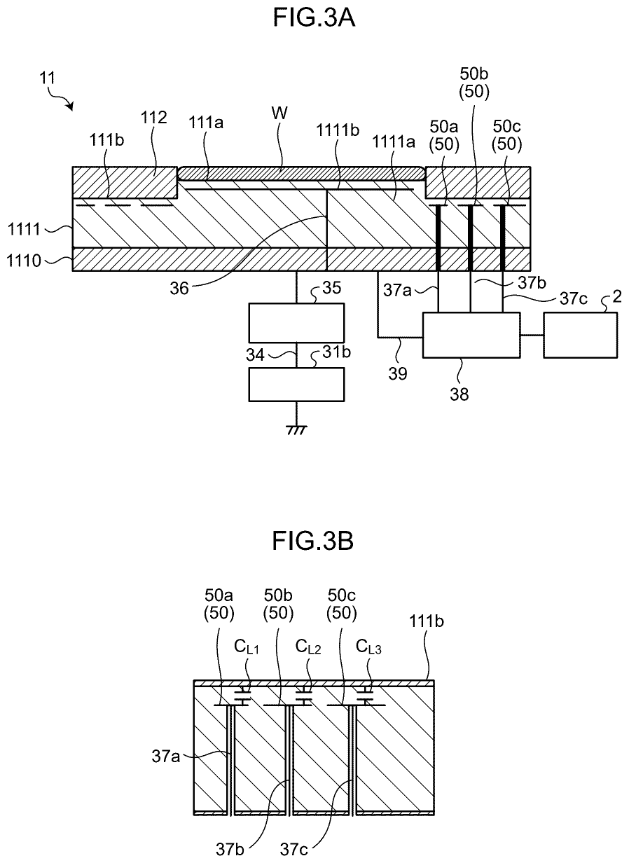

In FIGS. 2A and 2B, it is illustrated that the plurality of electrodes 50 (electrodes 50a to 50c) are arranged at different depths from the annular region 111b. However, the arrangement of the plurality of electrodes 50 is not limited thereto. An example of another configuration of the substrate support part 11 will be described. FIG. 3A is a cross-sectional view illustrating another example of a configuration of the main body part 111 of the substrate support part 11. FIG. 3B is an enlarged view of a portion of the electrostatic chuck 1111 in which the plurality of electrodes 50 are arranged. In the configuration illustrated in FIGS. 3A and 3B as well, three electrodes 50a to 50c are provided in a portion facing the ring assembly 112 inside the ceramic member 1111a. The electrodes 50a to 50c are formed such that the area of the surface facing the ring assembly 112 becomes larger in the order: the electrode 50a, the electrode 50b, and the electrode 50c, and are provided at the same depth from the annular region 111b. The capacitances between the electrodes 50a to 50c and the ring assembly 112 are illustrated as C_{L1} to C_{L3}. Since the electrodes 50a to 50c are formed such that the area of the surface facing the ring assembly 112 becomes larger in the order: the electrode 50a, the electrode 50b, and the electrode 50c, the capacitances C_{L1} to C_{L3} satisfy C_{L1}>C_{L2}>C_{L3}. Note that the order in which the area of the surface facing the ring assembly 112 becomes larger is not limited to the order: the electrode 50a, the electrode 50b, and the electrode 50c. For example, the electrodes 50a to 50c may be formed such that the area of the surface facing the ring assembly 112 becomes smaller in the order: the electrode 50a, the electrode 50b, and the electrode 50c, or may be formed such that the area of the surface facing the ring assembly 112 becomes smaller in the order: the electrode 50a, the electrode 50c, and the electrode 50b. That is, the order of magnitude between the areas of the surfaces of the electrodes 50a to 50c facing the ring assembly 112 may be arbitrarily changed.

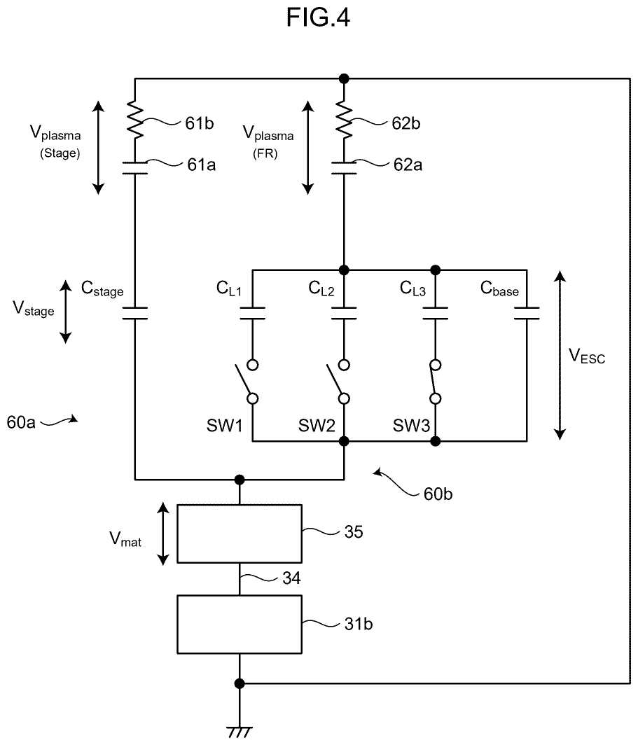

FIG. 4 is a circuit diagram schematically illustrating an example of a configuration of the plasma processing apparatus 1. FIG. 4 illustrates an equivalent circuit illustrating an electrical characteristic of a path through which a bias RF signal flows in the plasma processing apparatus 1.

The bias RF signal flows from the second RF generation unit 31b to the wire 34. The impedance matching circuit 35 provided on the wire 34 matches impedance on the second RF generation unit 31b side and impedance on the load side. The wire 34 branches into a path 60a and a path 60b. The path 60a indicates an electrical characteristic of the central region 111a of the base 1110. The path 60b indicates an electrical characteristic of the annular region 111b of the base 1110.

The capacitance C_{stage} of the path 60a indicates a capacitance between the central region 111a of the base 1110 and the substrate W. The resistor 61a and the capacitor 61b of the path 60a indicate electrical characteristics of plasma in the central region 111a.

The capacitances C_{L1} to C_{L3} of the path 60b indicate capacitances between the electrodes 50a to 50c of the annular region 111b and the ring assembly 112. The capacitance C_{base} of the path 60b indicates a capacitance between the annular region 111b of the base 1110 and the ring assembly 112. The switches SW1 to SW3 indicate switches of the switch mechanism 38 connected to the electrodes 50a to 50c, respectively. The resistor 62a and the capacitor 62b of the path 60b indicate electrical characteristics of plasma in the annular region 111b.

In the path 60b, the capacitances C_{L1} to C_{L3} connected in parallel with the capacitance C_{base} are switched by turning on and off the switches SW1 to SW3, and the overall capacitance changes. As a result, the potential of the ring assembly 112 changes.

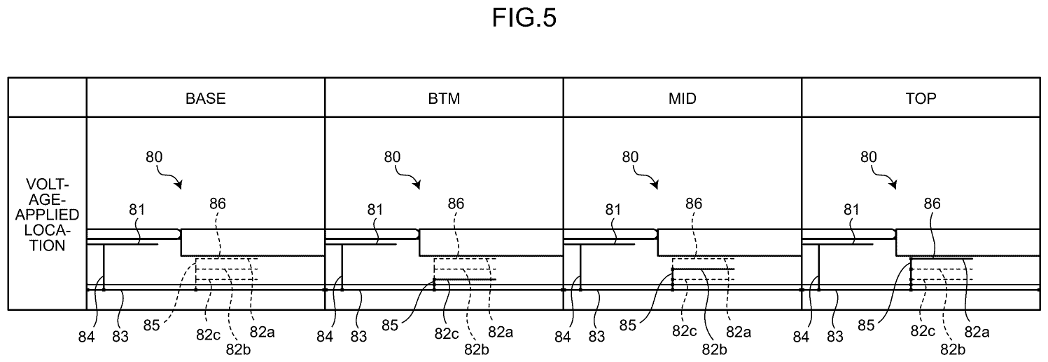

Here, an example of a result of simulating the change in potential of the ring assembly 112 will be described. FIG. 5 is a diagram for explaining a model used for simulation. FIG. 5 illustrates a model 80 that imitates the electrostatic chuck 1111, the base 1110, the ring assembly 112, and the substrate W. In the model 80, a line 81 that imitates the electrostatic electrode 1111b, lines 82a to 82c that imitate the electrodes 50a to 50c are provided, and a line 83 that imitates the base 1110 is provided. The line 82a is provided at a position 0.35 mm away from a surface 86 corresponding to the annular region 111b of the electrostatic chuck 1111. The line 82b is provided at a position 1.75 mm away from the surface 86. The line 82c is provided at a position 3.15 mm away from the surface 86. The line 83 is provided at a position 4.5 mm below the surface 86. The line 81 and the line 83 are connected by a line 84. The lines 82a to 82c and the line 83 are connected by a line 85. FIG. 5 illustrates the simulated cases as “BASE”, “BTM”, “MID”, and “TOP”. In each of the cases BASE, BTM, MID, and TOP, among the lines 81 to 85, a portion through which the bias RF signal flows is indicated by a solid line, and a portion through which the bias RF signal does not flow is indicated by a broken line. For example, in the BASE, the lines 81, 83, and 84 are indicated by solid lines, and the lines 82a to 82c and 85 are indicated by broken lines. From this, the BASE indicates a case where the bias RF signal flows through the electrostatic electrode 1111b and the base 1110, and the bias RF signal does not flow through the electrodes 50a to 50c. In the TOP, the lines 81, 82a, 83, 84, and 85 are indicated by solid lines, and the lines 82b and 82c are indicated by broken lines. From this, the TOP indicates a case where the bias RF signal flows through the electrostatic electrode 1111b, the electrode 50a, and the base 1110, and the bias RF signal does not flow through the electrodes 50b and 50c.

The BASE corresponds to a case where all the switches SW1 to SW3 are turned off in the equivalent circuit illustrated in FIG. 4. The BTM corresponds to a case where the switch SW3 is turned on and the switches SW1 and SW2 are turned off in the equivalent circuit illustrated in FIG. 4. The MID corresponds to a case where the switch SW2 is turned on and the switches SW1 and SW3 are turned off in the equivalent circuit illustrated in FIG. 4. The TOP corresponds to a case where the switch SW1 is turned on and the switches SW2 and SW3 are turned off in the equivalent circuit illustrated in FIG. 4.

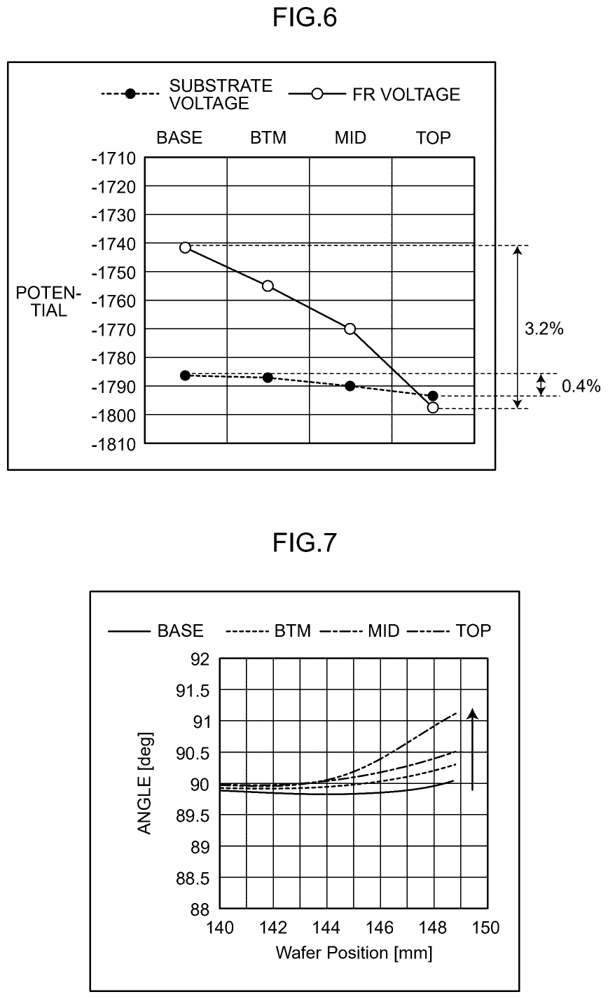

FIG. 6 is a diagram for explaining a simulation result. FIG. 6 illustrates a voltage at a portion of the substrate W (substrate voltage) and a voltage at a portion of the ring assembly 112 (FR voltage) of the model 80 when each of the cases BASE, BTM, MID, and TOP is simulated. FIG. 6 illustrates negative peak voltages generated by the bias RF signal as the substrate voltage and the FR voltage. The voltage at the portion of the substrate W (substrate voltage) changes little at BASE, BTM, MID, and TOP, and the change is 0.4%. On the other hand, the voltage at the portion of the ring assembly 112 (FR voltage) changes greatly at BASE, BTM, MID, and TOP, and the change is 3.2%.

Here, in a conventional method, a dielectric ring is disposed on a lower surface side of the ring assembly 112, and the potential of the ring assembly 112 is controlled by lifting and lowering the dielectric ring. However, in the conventional method, it is necessary to provide an upward-and-downward movement mechanism that moves the dielectric ring upward and downward, and particles may be generated from the upward-and-downward movement mechanism. In addition, the frequency of the bias RF signal is in the range of 100 kHz to 60 MHz as described above. In the conventional method, the lower the frequency of the bias RF signal, the less likely it is to function in controlling the potential of the ring assembly 112. For example, in a case where the frequency of the bias RF signal is set to 400 kHz, the conventional method cannot change the potential of the ring assembly 112 sufficiently.

On the other hand, in the plasma processing apparatus 1, the controller 2 controls the switch mechanism 38 to change the electrodes 50a to 50c through which the bias RF signal flows, so that the potential of the ring assembly 112 can be changed without providing the upward-and-downward movement mechanism. In the plasma processing apparatus 1, even when the bias RF signal has a low frequency, the controller 2 can sufficiently change the potential of the ring assembly 112 by controlling the switch mechanism 38 to change the electrodes 50a to 50c through which the bias RF signal flows.

By changing the potential of the ring assembly 112 in this manner, the plasma processing apparatus 1 can control the height of the plasma sheath surface in a peripheral portion of the substrate W. As a result, the plasma processing apparatus 1 can change the processing characteristic of plasma processing in the peripheral portion of the substrate W. For example, in a case where plasma etching is performed as the plasma processing, the plasma processing apparatus 1 can change the angle of hole in the peripheral portion of the substrate W.

FIG. 7 is a diagram for explaining a change in processing characteristic of plasma processing. FIG. 7 illustrates an angle of a hole in the peripheral portion (140 to 150 mm) of the substrate W when plasma etching is performed on the substrate W having a radius of 150 mm in each of the cases BASE, BTM, MID, and TOP. For example, even when the angle of the hole in the peripheral portion of the substrate W is substantially vertical (90 deg) at the BASE, the angle of the hole in the peripheral portion of the substrate W can be controlled by setting BTM, MID, and TOP.

The controller 2 controls the switch mechanism 38 to change the potential of the ring assembly 112, thereby controlling the processing characteristics of the plasma processing in the peripheral portion of the substrate W. For example, in the plasma processing apparatus 1, if the upper surface of the ring assembly 112 is worn away by plasma etching, the plasma sheath surface decreases in the peripheral portion of the substrate W, causing tilting in the peripheral portion of the substrate W. Therefore, the controller 2 controls the switch mechanism 38 to supply a bias RF signal to an electrode having a large capacitance (i.e., largest capacitance as compared to the other electrodes) with the ring assembly 112 as the ring assembly 112 is worn away. In the plasma processing apparatus 1, the tilting of hole formed in the substrate W gradually increases as the substrate W is repeatedly subjected to plasma processing and cleaning, and exceeds an allowable range. For example, the controller 2 regulates the potential of the ring assembly 112 when the tilting reaches a predetermined threshold value although it is within the allowable range. For example, the controller 2 controls the switch mechanism 38 so as to supply a bias RF signal to an electrode having a large capacitance with the ring assembly 112 every time the substrate W is plasma-etched a predetermined number of times the tilting exceeds the allowable range. For example, in a case where the bias RF signal is supplied to the electrode 50c at the time of plasma etching, the controller 2 controls the switch mechanism 38 to supply the bias RF signal to the electrode 50b or the electrode 50b. As a result, the plasma sheath surface in the peripheral portion of the substrate W can be raised, thereby making it possible to suppress tilting in the peripheral portion of the substrate W.

Note that the controller 2 may change the potential of the ring assembly 112 by controlling the switch mechanism 38 depending on the plasma processing to be performed. For example, in a case where process A and process B are performed as the plasma processing, the controller 2 may control the switch mechanism 38 to change the potential of the ring assembly 112 in the process A and the process B. In addition, the controller 2 may control the switch mechanism 38 during the plasma processing to change the potential of the ring assembly 112. In order to increase the potential of the ring assembly 112, the controller 2 controls the switch mechanism 38 to supply a bias RF signal to an electrode having a large capacitance with the ring assembly 112. In addition, in order to decrease the potential of the ring assembly 112, the controller 2 controls the switch mechanism 38 to supply a bias RF signal to an electrode having a small capacitance (i.e., smallest capacitance as compared to the other electrodes)with the ring assembly 112. Thus, the plasma processing apparatus 1 can change the potential of the ring assembly 112 depending on the plasma processing to be performed.

### Potential Control Method

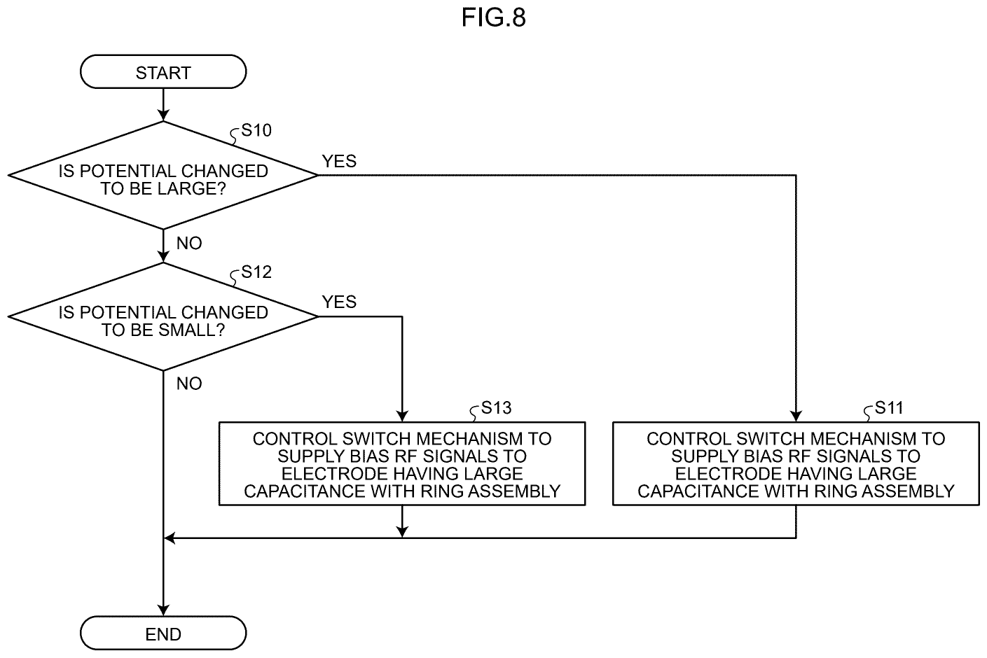

FIG. 8 is a flowchart illustrating an example of a processing flow of a potential control method. The processing illustrated in FIG. 8 is realized, when the potential of the ring assembly 112 is changed, by the processing unit 2a1 of the controller 2 reading a program from the storage 2a2 and executing the read program. For example, the controller 2 executes the processing to change the potential of the ring assembly 112 to be large every time the substrate W is plasma-etched a predetermined number of times the tilting exceeds the allowable range. In addition, the processing unit 2a1 executes the processing to change the potential of the ring assembly 112 to be large or small depending on the plasma processing to be performed.

The processing unit 2a1 determines whether to change the potential of the ring assembly 112 to be large (S10). When the potential of the ring assembly 112 is changed to be large (S10: Yes), the processing unit 2a1 controls the switch mechanism 38 to supply a bias RF signal to an electrode 50 having a large capacitance with the ring assembly 112 (S11), and ends the processing.

On the other hand, when the potential of the ring assembly 112 is not changed to be large (S10: No), the processing unit 2a1 determines whether to change the potential of the ring assembly 112 to be small (S12). When the potential of the ring assembly 112 is changed to be small (S12: Yes), the processing unit 2a1 controls the switch mechanism 38 to supply a bias RF signal to an electrode 50 having a small capacitance with the ring assembly 112 (S13), and ends the processing.

On the other hand, when the potential of the ring assembly 112 is not changed to be small (S12: No), the processing unit 2a1 ends the processing.

In the above-described one or more embodiments, the case where three electrodes 50 (electrodes 50a to 50c) are provided in a portion facing the ring assembly 112 inside the ceramic member 1111a has been described as an example. However, the disclosed technology is not limited thereto. The number of electrodes 50 may be two, or may be four or more.

In the above-described one or more embodiments, the case where the controller 2 controls the switch mechanism 38 so as to individually supply a bias RF signal to the plurality of electrodes 50 has been described as an example. However, the disclosed technology is not limited thereto. The controller 2 may control the switch mechanism 38 so as to supply a bias RF signal to one or more electrodes 50.

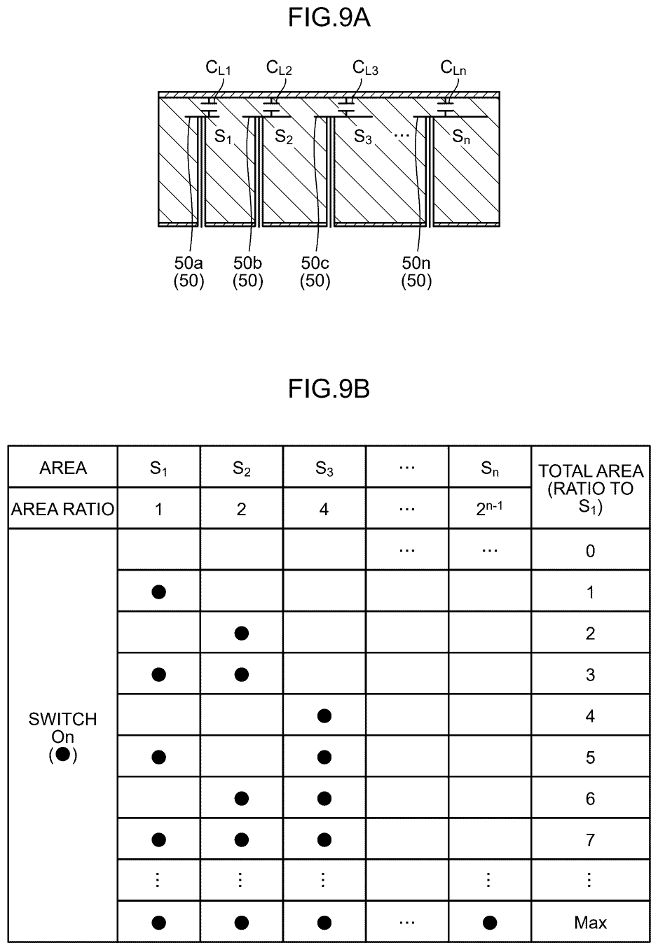

FIG. 9A is a diagram illustrating another example in which electrodes are arranged. In FIG. 9A, n electrodes 50a to 50n are provided in a portion facing the ring assembly 112 inside the ceramic member 1111a. The electrodes 50a to 50n are provided at the same depth from the annular region 111b. The electrodes 50a to 50n are formed such that the respective surfaces facing the ring assembly 112 have different areas S₁ to Sₙ, and the ratio of each of the areas is 2ⁿ⁻¹. Each of the electrodes 50a to 50n is connected to the switch mechanism 38. The switch mechanism 38 incorporates switches electrically connected to the electrodes 50a to 50n individually, and is configured to supply a bias RF signal to the electrodes 50a to 50n by switching each of the switches on/off. The controller 2 controls each of the switches of the switch mechanism 38 to be turned on/off so as to supply a bias RF signal to one or more electrodes 50. FIG. 9B is a diagram illustrating an example of a combination of switches turned on and off. FIG. 9B illustrates respective areas S₁ to Sₙ of the electrodes 50a to 50n and whether the switches are turned on or off for each switch on/off pattern. In the switch on/off pattern, a turned-on switch is indicated by “●”. In addition, FIG. 9B illustrates a total area of the electrodes 50 to which the bias RF signal is supplied by the switches that are turned on. The total area of the electrodes 50 is indicated by a ratio to the area S₁. Each switch on/off pattern is determined such that the ratio of the total area of the electrodes 50 to which the bias RF signal is supplied increases by 1. As a result, the total capacitance between the electrodes 50 that are switched on and the ring assembly 112 can be changed in a stepwise manner at regular intervals, so that the potential of the ring assembly can be controlled in a stepwise manner.

In the above-described one or more embodiments, the case where each of the plurality of electrodes 50 is formed in an annular shape to correspond to the annular region 111b of the electrostatic chuck 1111 to control the overall potential of the annular region 111b has been described as an example. However, the disclosed technology is not limited thereto. The annular region 111b of the electrostatic chuck 1111 may be divided into a plurality of zones, and a plurality of electrodes 50 may be provided in each zone so that the potential can be controlled for each zone.

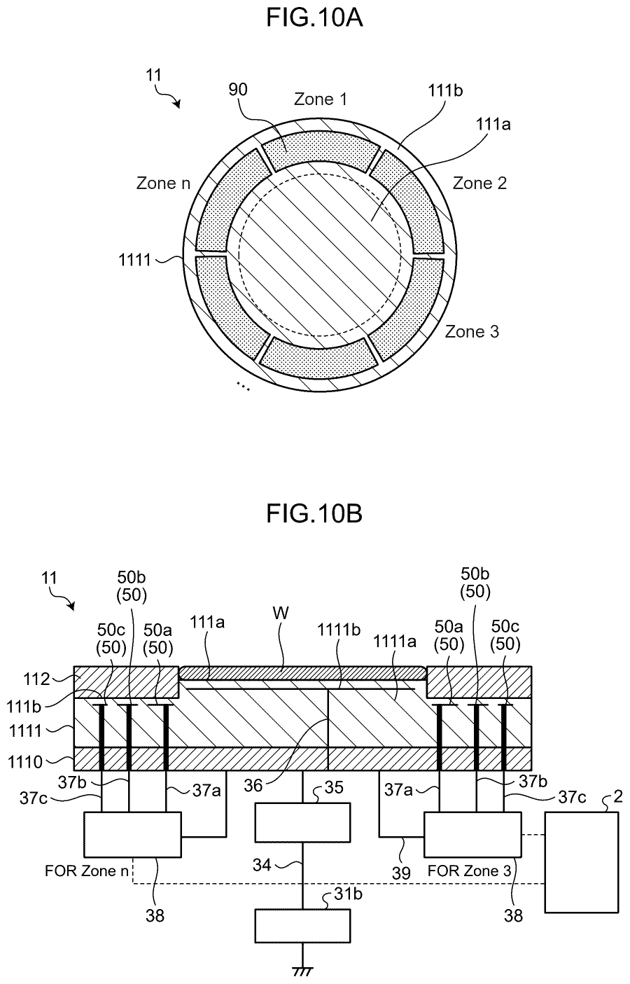

FIG. 10A is a diagram illustrating an example in which the annular region 111b of the electrostatic chuck 1111 is divided into a plurality of zones 90. FIG. 10A illustrates a case where the annular region 111b is divided into n zones 90 in the circumferential direction. In this case, a plurality of electrodes 50 and a switch mechanism 38 are provided for each zone 90. In each zone 90, the plurality of electrodes 50 are arranged according to the shape of the zone 90. FIG. 10B is a cross-sectional view illustrating an example of a configuration of the main body part 111 in a case where a plurality of electrodes 50 are provided for each zone 90. In FIG. 10B, three electrodes 50a to 50c and a switch mechanism 38 are provided in each of zone 3 and zone n. The controller 2 can control the potential for each zone 90 in the annular region 111b by controlling each of the switches of the switch mechanism 38 in each zone 90 to be turned on/off.

In the above-described one or more embodiments, the case where the bias RF signal is supplied to the electrostatic electrode 1111b and the switch mechanism 38 via the base 1110 has been described as an example. However, the disclosed technology is not limited thereto. For example, in the configurations of FIGS. 2A and 3A, the wire 36 and the wire 39 may be connected to the output side of the impedance matching circuit 35 of the wire 34, and the bias RF signal may be supplied to the electrostatic electrode 1111b and the switch mechanism 38 without passing through the base 1110.

In addition, the bias RF signal has a frequency in the range of 100 kHz to 60 MHz. In the above-described one or more embodiments, the potential of the ring assembly can be controlled by changing the total capacitance between the electrodes 50 and the ring assembly 112, so the bias RF signal is more effective in the region on the low frequency side. In particular, the bias RF signal desirably has a frequency in the range of 100 kHz to 13 MHz.

In the above-described one or more embodiments, the case where the bias power for attracting charged particles in plasma is high-frequency power (bias RF signal) has been described as an example. However, the disclosed technology is not limited thereto. The bias power may be a pulsed voltage. For example, the first DC generation unit 32a may generate a pulsed DC signal in the range of 100 kHz to 60 MHz, and supply the generated DC signal to the electrostatic electrode 1111b and the switch mechanism 38 as bias power. Note that, in a case where the bias RF signal is a pulsed DC signal, it is desirable to generate a pulsed DC signal in the range of 100 kHz to 13 MHz as in a case where the bias RF signal is high frequency power (bias RF signal).

The one or more embodiments has been described above. As described above, a plasma processing system according to the one or more embodiments includes a plasma processing chamber 10, an electrostatic chuck 1111 (stage), a plurality of electrodes 50, a power supply, a switch mechanism 38 (switch unit), and a controller 2. The plasma processing chamber 10 is configured such that plasma can be generated therein. The electrostatic chuck 1111 is disposed in the plasma processing chamber 10, formed of a dielectric material, and configured such that a substrate W can be placed thereon and a ring assembly 112 can be placed thereon around the substrate W. The plurality of electrodes 50 are provided in a portion facing the ring assembly 112 inside the electrostatic chuck 1111. The power supply is configured to supply bias power for attracting charged particles in the plasma. The switch mechanism 38 is configured to individually supply the bias power supplied from the power supply to the plurality of electrodes 50. The controller 2 controls the switch mechanism 38. Thus, the plasma processing system can control the potential of the ring assembly 112 without providing an upward-and-downward movement mechanism.

In addition, the plurality of electrodes 50 may be provided at different depths from the annular region 111b on which the ring assembly 112 of the electrostatic chuck 1111 is placed. In addition, the plurality of electrodes 50 may be provided at the same depth from the annular region 111b on which the ring assembly 112 of the electrostatic chuck 1111 is placed. In addition, the plurality of electrodes 50 may be formed in the same area. In addition, the plurality of electrodes 50 may be formed in different areas. The plasma processing system can change capacitances between the plurality of electrodes 50 and the ring assembly 112 by changing the depths of the electrodes 50 from the annular region 111b or the areas of the electrodes 50. In addition, the plasma processing system can control the potential of the ring assembly 112 by changing the number of electrodes 50 to which the bias power is supplied even if the electrostatic capacitances between the plurality of electrodes 50 and the ring assembly 112 are the same.

In addition, the plurality of electrodes 50 are n electrodes (n is a natural number of 2 or more), and are formed such that a ratio of each of the areas is 2ⁿ⁻¹. As a result, the plasma processing system can change the total capacitance with the ring assembly 112 in a stepwise manner by a constant amount, so that the potential of the ring assembly can be controlled in a stepwise manner.

In addition, the controller 2 controls the switch mechanism 38 to supply bias power to an electrode 50 having a large capacitance with the ring assembly 112 when increasing the potential of the ring assembly 112, and controls the switch mechanism 38 to supply bias power to an electrode 50 having a small capacitance with the ring assembly 112 when decreasing the potential of the ring assembly 112. Thus, the plasma processing system can control the potential of the ring assembly 112.

In addition, the controller 2 controls the switch mechanism 38 to supply bias power to an electrode 50 having a large capacitance with the ring assembly 112 as the ring assembly 112 is worn away. As a result, the plasma processing system can suppress an occurrence of tilting in the peripheral portion of the substrate W.

It should be understood that the one or more embodiments disclosed herein are illustrative in all respects and are not restrictive. Indeed, the one or more embodiments may be embodied in various forms. The above-described one or more embodiments may be omitted, replaced, or modified in various forms without departing from the scope and spirit of the appended claims.

In addition, regarding the above-described embodiments, the following supplementary notes are further disclosed.

According to the present disclosure, the potential of the ring assembly can be controlled without providing an upward-and-downward movement mechanism.

Although the present disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

In connection with the above one or more embodiments, the following notes are further disclosed.

### (Note 1)

A plasma processing apparatus comprising:
a chamber to generate plasma therein;
a stage disposed in the chamber, formed of a dielectric material, receives a substrate thereon and receives a ring assembly thereon around the substrate;
a plurality of electrodes provided in a portion facing the ring assembly inside the stage;
a power supply supplying bias power for attracting charged particles in the plasma;
a switch individually supplying the bias power supplied from the power supply to the plurality of electrodes; and
a controller configured to control the switch.

### (Note 2)

The plasma processing apparatus according to note 1, wherein
the plurality of electrodes are provided at different depths from a region of the stage where the ring assembly is placed.

### (Note 3)

The plasma processing apparatus according to note 1, wherein
the plurality of electrodes are provided at the same depth from a region of the stage where the ring assembly is placed.

### (Note 4)

The plasma processing apparatus according to any one of notes 1 to 3, wherein
the plurality of electrodes have the same area of surfaces facing the ring assembly.

### (Note 5)

The plasma processing apparatus according to any one of notes 1 to 3, wherein
the plurality of electrodes have different areas of surfaces facing the ring assembly.

### (Note 6)

The plasma processing apparatus according to note 5, wherein
the plurality of electrodes are n electrodes (n is a natural number of 2 or more), and are formed such that a ratio of each of the areas of the surfaces facing the ring assembly is 2ⁿ⁻¹.

### (Note 7)

The plasma processing apparatus according to any one of notes 1 to 6, wherein
the plurality of electrodes do not overlap each other.

### (Note 8)

The plasma processing apparatus according to any one of notes 1 to 7, wherein
the controller circuitry is configured to control the switch to supply the bias power to a first electrode having a largest capacitance, among the plurality of electrodes, with the ring assembly when increasing a potential of the ring assembly, and controls the switch unit to supply the bias power to a second electrode having a smallest capacitance, among the plurality of electrodes, with the ring assembly when decreasing the potential of the ring assembly.

### (Note 9)

The plasma processing apparatus according to any one of notes 1 to 7, wherein
the controller circuitry is configured to control the switch to supply the bias power to an electrode, among the plurality of electrodes, having a largest capacitance with the ring assembly as the ring assembly is worn away.

### (Note 10)

The plasma processing apparatus according to any one of notes 1 to 9, wherein
the power supply is a high-frequency power supply supplying high-frequency power as the bias power.

### (Note 11)

The plasma processing apparatus according to any one of notes 1 to 9, wherein
the power supply is a DC power supply generating a pulsed voltage as the bias power.

(Note 12)

A potential control method in a plasma processing apparatus comprising:
providing the plasma processing apparatus comprising:
   a chamber including a stage,
   a plurality of electrodes provided in a portion facing the ring assembly inside the stage;
   a power supply;
   a switch; and
   controller circuitry, the method comprising
by the controller circuitry, controlling the switch to supply bias power to a first electrode, among the plurality of electrodes, having a largest capacitance with the ring assembly when increasing a potential of the ring assembly, and
controlling the switch to supply the bias power to second electrode, among the plurality of electrodes, having a smallest capacitance with the ring assembly when decreasing the potential of the ring assembly.

### (Note 13)

The potential control method according to note 12, wherein
the plurality of electrodes are provided at different depths from a region of the stage where the ring assembly is placed.

### (Note 14)

The potential control method according to note 12, wherein
the plurality of electrodes are provided at the same depth from a region of the stage where the ring assembly is placed.

### (Note 15)

The potential control method according to note 12, wherein
the plurality of electrodes have the same area of surfaces facing the ring assembly.

### (Note 16)

The potential control method according to note 12, wherein
the plurality of electrodes have different areas of surfaces facing the ring assembly.

### (Note 17)

The potential control method according to note 16, wherein
the plurality of electrodes are n electrodes (n is a natural number of 2 or more), and are formed such that a ratio of each of the areas of the surfaces facing the ring assembly is 2ⁿ⁻¹.

### (Note 18)

The potential control method according to note 12, wherein
the plurality of electrodes do not overlap each other.

### (Note 19)

A plasma processing apparatus comprising:
a chamber to generate plasma therein;
a stage disposed in the chamber, formed of a dielectric material, and receiving a substrate thereon and the stage receiving a ring assembly thereon around the substrate,
wherein an annular region of the stage is divided into a plurality of zones, and the plurality of electrodes are provided for each zone;
a plurality of electrodes provided in a portion facing the ring assembly inside the stage;
a power supply supplying bias power for attracting charged particles in the plasma;
a switch individually supplying the bias power supplied from the power supply to the plurality of electrodes; and
controller circuitry configured to control the switch to independently adjust a potential for each zone.

### (Note 20).

The plasma processing apparatus according to note 19, wherein
each of the plurality of electrodes is formed in an annular shape to correspond to an annular region of the electrostatic chuck.

What is claimed is:

1. A plasma processing apparatus comprising:
a chamber to generate plasma therein;
a stage disposed in the chamber, formed of a dielectric material, receives a substrate thereon and receives a ring assembly thereon around the substrate;
a plurality of electrodes provided in a portion facing the ring assembly inside the stage;
a power supply supplying bias power for attracting charged particles in the plasma;
a switch individually supplying the bias power supplied from the power supply to the plurality of electrodes; and
controller circuitry configured to control the switch.

2. The plasma processing apparatus according to claim 1, wherein
the plurality of electrodes are provided at different depths from a region of the stage where the ring assembly is placed.

3. The plasma processing apparatus according to claim 1, wherein
the plurality of electrodes are provided at the same depth from a region of the stage where the ring assembly is placed.

4. The plasma processing apparatus according to claim 1, wherein
the plurality of electrodes have the same area of surfaces facing the ring assembly.

5. The plasma processing apparatus according to claim 1, wherein
the plurality of electrodes have different areas of surfaces facing the ring assembly.

6. The plasma processing apparatus according to claim 5, wherein
the plurality of electrodes are n electrodes (n is a natural number of 2 or more), and are formed such that a ratio of each of the areas of the surfaces facing the ring assembly is 2ⁿ⁻¹.

7. The plasma processing apparatus according to claim 1, wherein
the plurality of electrodes do not overlap each other.

8. The plasma processing apparatus according to claim 1, wherein
the controller circuitry is configured to:
control the switch to supply the bias power to a first electrode, among the plurality of electrodes, having a largest capacitance with the ring assembly when increasing a potential of the ring assembly, and
control the switch to supply the bias power to a second electrode, among the plurality of electrodes, having a smallest capacitance with the ring assembly when decreasing the potential of the ring assembly.

9. The plasma processing apparatus according to claim 1, wherein
the controller circuitry is configured to control the switch to supply the bias power to an electrode, among the plurality of electrodes, having a largest capacitance with the ring assembly as the ring assembly is worn away.

10. The plasma processing apparatus according to claim 1, wherein
the power supply is a high-frequency power supply supplying high-frequency power as the bias power.

11. The plasma processing apparatus according to claim 1, wherein
the power supply is a DC power supply generating a pulsed voltage as the bias power.

12. A potential control method in a plasma processing apparatus comprising:
providing the plasma processing apparatus comprising:
a chamber including a stage,
a plurality of electrodes provided in a portion facing the ring assembly inside the stage;
a power supply;
a switch; and
controller circuitry, the method comprising:
by the controller circuitry:
controlling the switch to supply bias power to a first electrode, among the plurality of electrodes, having a largest capacitance with the ring assembly when increasing a potential of the ring assembly, and
controlling the switch to supply the bias power to a second electrode, among the plurality of electrodes, having a smallest capacitance with the ring assembly when decreasing the potential of the ring assembly.

13. The potential control method according to claim 12, wherein
the plurality of electrodes are provided at different depths from a region of the stage where the ring assembly is placed.

14. The potential control method according to claim 12, wherein
the plurality of electrodes are provided at the same depth from a region of the stage where the ring assembly is placed.

15. The potential control method according to claim 12, wherein
the plurality of electrodes have the same area of surfaces facing the ring assembly.

16. The potential control method according to claim 12, wherein
the plurality of electrodes have different areas of surfaces facing the ring assembly.

17. The potential control method according to claim 16, wherein
the plurality of electrodes are n electrodes (n is a natural number of 2 or more), and are formed such that a ratio of each of the areas of the surfaces facing the ring assembly is 2ⁿ⁻¹.

18. The potential control method according to claim 12, wherein
the plurality of electrodes do not overlap each other.

19. A plasma processing apparatus comprising:
a chamber to generate plasma therein;
a stage disposed in the chamber, formed of a dielectric material, and receiving a substrate thereon and the stage receiving a ring assembly thereon around the substrate;
a plurality of electrodes provided in a portion facing the ring assembly inside the stage,
wherein an annular region of the stage is divided into a plurality of zones, and the plurality of electrodes are provided for each zone;
a power supply supplying bias power for attracting charged particles in the plasma;
a switch individually supplying the bias power supplied from the power supply to the plurality of electrodes; and
controller circuitry configured to control the switch to independently adjust a potential for each zone.

20. The plasma processing apparatus according to claim 19, wherein
each of the plurality of electrodes is formed in an annular shape to correspond to an annular region of the electrostatic chuck.
